(19) United States
(12) Patent Application Publication
(10) Pub. No.: US 2008/0129153 A1
(43) Pub. Date: Jun. 5, 2008

(54) Inertial energy scavenger

(76) Inventors: Shadrach J. Roundy, Concord, CA (US); Jeffry Tola, Upland, CA (US); Jeffrey F. Tola, Los Angeles, CA (US)

Correspondence Address: LUMEN PATENT FIRM, INC., 2345 YALE STREET, SECOND FLOOR, PALO ALTO, CA, 94306, US

(21) Appl. No.: 11/803,900

(22) Filed: May 15, 2007

Related U.S. Application Data
(60) Provisional application No. 60/817,981, filed on Jun. 30, 2006.

(51) Int. Cl. H01L 41/02

(52) U.S. Cl. 310/339

(57) ABSTRACT

The present invention provides an inertial energy scavenger that includes at least one piezoelectric element held by a housing, a proof mass that is movable within the housing in a direction parallel to the piezoelectric element, and a mechanical assembly disposed between the proof mass and the piezoelectric element. The mechanical assembly transfers work from the proof mass to the piezoelectric element, where the work from the proof mass is a first force along a first distance and the work to the piezoelectric element is a second force along a second distance. The first distance is greater than the second distance and the first force is smaller than the second force. Force amplification is determined by the geometry of the mechanical transfer assembly and can range anywhere from just above 1 to at least 10, where some embodiments include a bi-lever configuration, a tube-shaped configuration and a reverse actuation configuration.

### CROSS-REFERENCE TO RELATED APPLICATIONS

This application is cross-referenced to and claims the benefit from U.S. Provisional Patent Application 60/817,981 filed Jun. 30, 2006, which is hereby incorporated by reference.

### FIELD OF THE INVENTION

The present invention relates generally to energy scavenging devices. More particularly, the present invention relates force amplification in piezoelectric inertial energy scavenging.

### BACKGROUND

Inertial energy scavengers convert ambient motion, such as vibration, into electrical energy useful for powering electronic devices such as sensors and the like. Such energy scavengers are attractive as an alternative to batteries in many applications including, but not limited to tire pressure monitoring, industrial process control, supply chain management, building thermal control, and transportation. Additionally, many long-life applications are enabled by inertial energy scavengers.

Piezoelectric material converts mechanical strain to electrical energy by creating a charge separation across a dielectric material. Piezoelectric material is often used as the transduction mechanism in energy scavenging applications because it provides an inherently high energy coupling between mechanical and electrical domains. The voltages produced by the material are high enough to be easily manipulated and conditioned for use by sensors and electronics. Piezoelectric material is relatively stiff, therefore making it more useful for relatively high-frequency applications.

Piezoelectric energy scavengers often consist of bending a piezoelectric plank secured at one end and moveable at the opposing end. This configuration provides a less rigid material structure, lowering the useful frequency range of the scavenger. However, such beam configurations are still too stiff to provide a robust coupling with excitation sources that are below about 25 Hz.

The potential energy generated by a piezoelectric element is proportional to its volume multiplied by its average mechanical strain. In the case of inertial energy scavengers formed by a horizontal plank having a proof mass attached to the moving end, the strain in the piezoelectric material is produced by the motion of the proof mass. For each cycle, the amount of work done by the proof mass on the piezoelectric element is proportional to its mass multiplied by the distance traveled. At high-frequencies, the dynamics of the system under commonly occurring excitation sources usually limit the motion of the proof mass to very small displacements. However, at lower frequencies the proof mass can undergo larger displacements (on the order of several millimeters). Piezoelectric structures are usually unable to flex or displace this far unless they are very large and/or actuated by a large proof mass. However, in order to maximize the work done by the proof mass at low frequencies, it is important not to limit its motion too much by directly coupling it with a stiff transducer.

A further difficulty with piezoelectric elements used as energy scavengers is that most piezoelectric materials (such as PZT and its variants) are brittle, can fatigue with many stress cycles, particularly under tension, and can crack if overstrained or in response to shock. These issues are more of a problem in low frequency and high displacement applications because the piezoelectric material is typically straining to a higher level on each cycle.

Accordingly, there is a need in the art to increase the performance and robustness of inertial piezoelectric energy scavengers, particularly for low frequency applications.

### SUMMARY OF THE INVENTION

The present invention provides an inertial energy scavenger that includes at least one piezoelectric element held by a housing, a proof mass that is movable within the housing in a direction that is parallel to the piezoelectric element, and a mechanical assembly disposed between the proof mass and the piezoelectric element. The mechanical assembly transfers work from the proof mass to the piezoelectric element, where the work from the proof mass is a first force along a first distance and the work to the piezoelectric element is a second force along a second distance. The first distance is greater than the second distance and the first force is smaller than the second force.

In one aspect of the invention, the piezoelectric element is a cantilever piezoelectric element having a first end connected to the housing and a second end coupled to the mechanical assembly. In one aspect, the cantilever first end is larger than the cantilever second end.

According to another aspect, the piezoelectric element is a fixed-fixed supported piezoelectric element having a first end and a second end connected to the housing and a middle section coupled to the mechanical assembly.

In a further aspect of the invention, the housing has at least one displacement control surface interfacing the piezoelectric element, where the control surface is curved.

In another aspect of the invention, the proof mass within the housing has at least one stable equilibrium point, where when the proof mass is at the stable equilibrium point the piezoelectric element is at a minimum deflection.

According to another aspect, the proof mass within the housing has at least one unstable equilibrium point, where when the proof mass is in the unstable equilibrium point the piezoelectric element is at a maximum deflection.

In one embodiment, the mechanical assembly has at least one bi-lever work transfer element and at least one piezoelectric element coupler. According to one aspect of the embodiment, the bi-lever work transfer element has a proof mass connection end, where the connection end connects the proof mass to the bi-lever. The bi-lever work transfer element further has a top lever having a top lever first end, a top lever middle section, and a top lever second end, where the top lever first end is attached to the proof mass connection end, and the top lever middle section extends in a first diagonal direction from the connection end. Additionally, the bi-lever work transfer element has a coupler span having a coupler span top end, a coupler span middle section, and a coupler span bottom end, where the coupler span top end is connected to the second end of the top lever, and the coupler span middle section is disposed along the piezoelectric element. The bi-lever work transfer element further has a bottom lever having a bottom lever first end, a bottom lever middle section, and a bottom lever second end, where the bottom lever first end is attached to the coupler span bottom end, and the bottom lever middle section extends in a second diagonal direction from the coupler span bottom end, in which the bottom lever second end slidably contacts a planar surface within the housing. The planar surface is perpendicular to the movement of the proof mass. The work from the proof mass has a first force along a first distance and the work to the piezoelectric element has a second force along a second distance, where the first distance is greater than the second distance and the first force is smaller than the second force.

In one aspect of this embodiment, the piezoelectric element coupler has a coupler span retaining surface and a coupler cavity, where the retaining surface slidably holds the coupler span and the coupler cavity fixedly holds a movable end of the piezoelectric element such that the coupler pushes and pulls the piezoelectric element according to motion by the proof mass.

In another aspect of this embodiment, the piezoelectric element coupler has a coupler span retaining surface and a coupler cavity, whereby the retaining surface fixidly holds the coupler span and the coupler cavity slidably holds a movable end of the piezoelectric element, where the coupler pushes and pulls the piezoelectric element according to motion by the proof mass.

In a further aspect, the coupler span middle section has a sliding surface that enables the coupler span middle section to slide on the piezoelectric element as the proof mass moves, where the coupler span middle section moves the piezoelectric element.

In yet another aspect, the coupler span middle section has a rounded surface that rolls on the piezoelectric element as the proof mass moves, where the coupler span middle section moves the piezoelectric element.

In one embodiment of the invention, the housing has a track having a first end and a second end, where the proof mass moves therein. The housing further has a first proof mass stop disposed at the track first end and a second proof mass stop disposed at the track second end, and a first restoring spring disposed at the first stop and a second restoring spring disposed at the second stop. In this embodiment, the mechanical assembly has at least one actuation channel disposed transverse to a longitudinal length of the track. The actuation channel holds a mechanical transfer element that is moveable within the actuation channel. The mechanical transfer element abuts the piezoelectric element, and the proof mass abuts the mechanical transfer element to move the mechanical transfer element within the actuation channel. The mechanical transfer element moves the piezoelectric element as the proof mass moves between the restoring springs according to forces applied to the housing. The work from the proof mass has a first force along a first distance and the work to the piezoelectric element has a second force along a second distance, where the first distance is greater than the second distance and the first force is smaller than the second force.

In one aspect of this embodiment, the mechanical transfer element is an actuation ball that rolls within the actuation channel. In a further aspect, the mechanical transfer element can be an actuation cylinder that has a rounded top and a rounded bottom, where the actuation cylinder is slidable within the actuation channel. In another aspect, the housing holds the piezoelectric element outside of the track.

In a further aspect, the proof mass is a spherical proof mass. Additionally the track may be a tube or a curved tube, where the curved tube may be a constant-radius tube or a variable-radius tube.

In another embodiment of the invention, the energy scavenger has at least one piezoelectric element held by a translating housing, where the translation is in a direction parallel to the piezoelectric element and the motion is relative to a stationary base and cover. A proof mass is held in the housing, where the housing rolls on at least one roller having a roller axis perpendicular to the translation direction, where the axis couples to a bearing in the housing. The housing has at least one actuator channel, where the actuator channel is along the translation direction. Further, the base has at least one actuator disposed perpendicular to the base planar surface, where the actuator channel of the housing holds the actuator therein when the housing translates. The current embodiment further has a mechanical assembly disposed between the actuator channel and the piezoelectric element, where the mechanical assembly transfers work from the proof mass to the piezoelectric element when acted on by the actuator. The work from the proof mass has a first force along a first distance and the work to the piezoelectric element has a second force along a second distance, where the first distance is greater than the second distance and the first force is smaller than the second force.

In one aspect of this embodiment, the proof mass is an effective proof mass that has at least one roller having a roller axis perpendicular to the translation direction, at least one piezoelectric element, the housing, the mechanical assembly, and the energy scavenger electronics. Here, work from the effective proof mass has an effective force along the first distance and work to the piezoelectric element has a second effective force along the second distance, where the first distance is greater than the second distance and the first effective force is smaller than the second effective force.

In another aspect, the piezoelectric element is a cantilever piezoelectric element having a first end connected to the housing and a second end coupled to the mechanical assembly.

In another aspect, the cantilever first end is larger than the cantilever second end.

In a further aspect, the piezoelectric element is a fixed-fixed supported piezoelectric element having a first end and a second end connected to the housing and a middle section coupled to the mechanical assembly.

In another aspect, the housing has at least one displacement control surface interfacing the piezoelectric element, where the control surface is curved.

In yet another aspect of the current embodiment, the actuator has an angled surface disposed perpendicular to the base.

In another aspect, the mechanical assembly has a work transfer port that spans from an inside wall of the actuator channel through an outside wall of the housing, and a work transfer element that moves within the transfer port when acted on by the actuator. Here, in one aspect, the work transfer element can be a roller ball or a sliding cylinder.

In one aspect of the current embodiment, the base further has restoring springs, where the restoring springs are disposed to oppose the housing translation.

Some key advantages of the invention are robust performance at relatively low frequencies in a wide range of applications. Because piezoelectric structures are generally stiff, a force amplification mechanism allows the relatively high displacement (characteristic of low frequency applications) and low force motion of the proof mass to be converted to a high-force/low-displacement motion that couples better with the piezoelectric device. The invention reorients the direction of motion, which allows a reduction in the overall installation volume of the energy scavenger without sacrificing energy output. A single proof mass can actuate multiple piezoelectric structures that are oriented out-of-plane to each other, which can improve the energy output for a given installation volume. The transfer mechanism enables bi-stable motion of the proof mass which can improve the performance, and also contains features that provide robustness functions, where the mechanism inherently limits the maximum strain the piezoelectric device can see without resorting to limit stops that can transfer shocks to the piezoelectric material and represent manufacturing tolerance constraints. A piezoelectric surface profile in the housing supports the piezoelectric structure while under load to provide reduced peak strain levels in the piezoelectric structure. For example, constant curvature surface, onto which the piezoelectric element deflects, greatly reduces the stress concentrations, thereby reducing the possibility of fatigue cracking. This surface also provides the opportunity for the transfer mechanism to bias the piezoelectric element in compression, which reduces the risk of tension fatigue cracking. The transfer mechanism is implemented with compliant mechanisms without joints that can create energy reducing friction and unwanted component wear. Another key advantage is the transfer mechanism can be implemented with rolling structures that provide very low friction and very high out of plane stiffness.

### BRIEF DESCRIPTION OF THE FIGURES

The objectives and advantages of the present invention will be understood by reading the following detailed description in conjunction with the drawing, in which:

FIGS. 1(a)-1(c) show planar and perspective views of a cross-spring inertial piezoelectric energy scavenger according to the present invention.

FIGS. 2(a)-(c) show planar partial-cutaway views of a tube-shaped inertial piezoelectric energy scavenger according to the present invention.

FIGS. 3(a)-3(c) show an exploded perspective view and a planar top view of an effective proof mass inertial piezoelectric energy scavenger according to the present invention.

### DETAILED DESCRIPTION OF THE INVENTION

Although the following detailed description contains many specifics for the purposes of illustration, anyone of ordinary skill in the art will readily appreciate that many variations and alterations to the following exemplary details are within the scope of the invention. Accordingly, the following preferred embodiments of the invention are set forth without any loss of generality to, and without imposing limitations upon, the claimed invention.

The present invention provides inertial piezoelectric energy scavengers. The inertial piezoelectric energy scavengers according to the current invention generally contain a proof mass, which actuates a piezoelectric structure. The proof mass is driven by external motion inputs such as vibrations. The invention has a mechanical transfer assembly that mechanically couples the proof mass to the piezoelectric structure. The mechanical transfer assemblies significantly improve the performance of the scavenger by providing force amplification in converting relatively high-displacement and low-force motion of the proof mass into high-force and low-displacement motion of the piezoelectric structure. This allows more energy input into the system while not limiting the motion of the proof mass. Furthermore, it allows a stiffer piezoelectric structure to be used which is both more robust, and can contain more piezoelectric material which in turn can provide more energy output. These stiffer materials are easily manufactured, which enhances manufacturing sourcing options and ultimately improves total cost of manufacturing.

The mechanical transfer assembly reorients the direction of motion of the proof mass and allows the long axis of a piezoelectric beam to be parallel to the motion axis of the proof mass, which achieves greater installation volume efficiency and allows a single proof mass to actuate multiple piezoelectric structures. This is useful in improving the energy output for a given volume.

The mechanical transfer assembly can also provide a bi-stable motion of the proof mass. The proof mass has at least one stable equilibrium point at which the piezoelectric beam is at its minimum deflection, and at least one unstable equilibrium point where the piezoelectric beam is at its maximum deflection point. The piezoelectric beam can be a cantilever beam fixed at one end or a fixed-fixed beam secured at both ends. As the proof mass moves, it passes an unstable equilibrium point. This behavior both limits the maximum strain in the piezoelectric beam and increases the strain rate through its maximum deflection point. The mechanical transfer assembly can be implemented in many ways, and are described below.

In addition to improving the electrical output performance of the energy scavenger, the mechanical transfer assembly contains unique features that improve the system's robustness by reducing overstrain due to high level excitation or unanticipated shocks, limiting fatigue cracking of the piezoelectric ceramic, particularly in tension, and restricting stress concentrations in a flexing piezoelectric beam. The mechanical transfer assembly, according to the embodiments of the current invention, prevents overstrain of the piezoelectric material due to large inputs. The output motion magnitude of the mechanical transfer assembly used to actuate the piezoelectric beam is controlled by solely dimensional features of the mechanism and can only move through a set pathway or distance regardless of the magnitude of the input excitation. Therefore, the maximum stress in the piezoelectric structure is predetermined without the use of limit stops. While beam limit stops could be used to limit the deflections of the piezoelectric structure, the impact caused by contacting the limit stop could cause unwanted stress shocks in the piezoelectric material. The use of limit stops also introduces the need for additional manufacturing process controls which can ultimately increase costs or reduce reliability. Therefore, limiting the deflection of the piezoelectric structure by means other than a limit stop greatly improves the robustness of the energy scavenger. The mechanical transfer assembly can be assembled such that at the maximum travel of the proof mass, the piezoelectric structure has a compressive stress bias. As the piezoelectric device is AC coupled, any DC offset in stress level does not affect its output. However, by including a slight compressive bias, the risk of fatigue cracking is greatly reduced as the system can be designed such that the piezoelectric material does not go into tension. Finally, the deflection characteristics of the piezoelectric beam can be controlled with a constant curvature displacement control surface. The constant curvature surface limits the stress concentration, and ensures constant strain along the length of the element, which provides for more efficient transfer of energy between mechanical and electrical domains. A further embodiment to ensure constant strain along the length of the element, according to the current invention, is to shape a beam so that it is wider at the base and narrower at the free end.

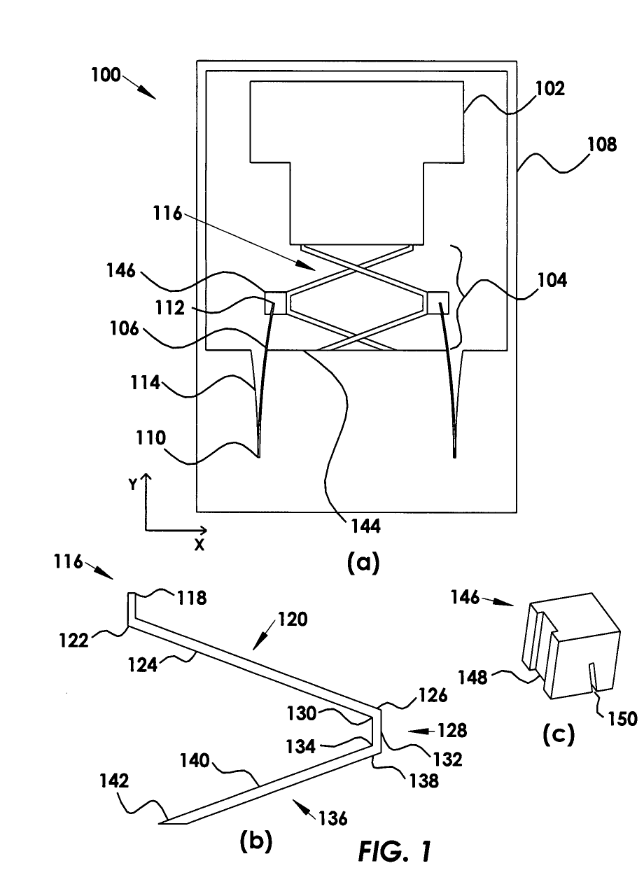

Referring now to the figures, FIGS. 1(a)-1(c) show planar and perspective views of one embodiment of the invention, where a cross-spring inertial piezoelectric energy scavenger 100 with a mechanical transfer assembly 104 is shown. In this embodiment, the proof mass 102 moves in the direction of the y-axis, and the mechanical transfer assembly 104 reorients that motion along the x-axis. The force amplification ratio is determined by the geometry of the mechanical transfer assembly 104 and can range anywhere from just above 1 to at least 10. As shown, the inertial energy scavenger 100 includes at least one piezoelectric 106 element held by a housing 108, the proof mass 102 is movable within the housing 108 in a direction that is parallel to the piezoelectric element 106. The mechanical assembly 104 is disposed between the proof mass 102 and the piezoelectric element 106. The mechanical assembly 104 transfers work from the proof mass 102 to the piezoelectric element 106, where the work from the proof mass 102 is a first force along a first distance and the work to the piezoelectric element 106 is a second force along a second distance. The first distance is greater than the second distance and the first force is smaller than the second force.

In the embodiment of the invention shown in FIGS. 1(a) and 1(b), the piezoelectric element 106 is a cantilever piezoelectric element 106 having a first end 110 connected to the housing 108 and a second end 112 coupled to the mechanical assembly 104. In one aspect, the cantilever first end 110 is larger than the cantilever second end 112 (not shown). Not shown in the figures, but it should be obvious that the piezoelectric element 106 can be a fixed-fixed supported piezoelectric element 106 having a first end 110 and a second end 112 connected to the housing 108 and a middle section coupled to the mechanical assembly 104.

FIG. 1(a) further shows the housing 108 having at least one displacement control surface 114 interfacing the piezoelectric element 106, where the control surface 114 is curved. Here, the proof mass 102 within the housing 108 has one stable equilibrium point, when the proof mass 102 is at the stable equilibrium point the piezoelectric element 106 is at a minimum deflection. Further, the proof mass 102 within the housing 108 has two unstable equilibrium points, where when the proof mass 102 is in the unstable equilibrium point the piezoelectric element 106 is at a maximum deflection.

The mechanical assembly 104 has at least one bi-lever work transfer element 116 and at least one piezoelectric element coupler 118. The bi-lever work transfer element 116, shown in FIGS. 1(a) and 1(b), has a proof mass connection end 118, where the connection end 118 connects the proof mass 102 to the bi-lever 116. The bi-lever work transfer element 116 further has a top lever 120 having a top lever first end 122, a top lever middle section 124, and a top lever second end 126, where the top lever first 122 end is attached to the proof mass connection end 118, and the top lever middle section 124 extends in a first diagonal direction from the connection end 118. Additionally, the bi-lever work transfer element 116 has a coupler span 128 having a coupler span top end 130, a coupler span middle section 132, and a coupler span bottom end 134. The coupler span top end 130 is connected to the top lever second end 126, and the coupler span middle section 132 is disposed parallel to the piezoelectric element 106. The bi-lever work transfer element 116 further has a bottom lever 136 having a bottom lever first end 138, a bottom lever middle section 140, and a bottom lever second end 142, where the bottom lever first end 138 is attached to the coupler span bottom end 134, and the bottom lever middle section 140 extends in a second diagonal direction from the coupler span bottom end 132, in which the bottom lever second end 142 slidably contacts a planar surface 144 (see FIG. 1(a)) within the housing 108. The planar surface 144 is perpendicular to the movement of the proof mass 102.

FIGS. 1(a) and 1(c) show a piezoelectric element coupler 146 having a coupler span retaining surface 148 and a coupler cavity 150, where the retaining surface 148 slidably holds the coupler span 128 and the coupler cavity 150 fixedly holds a movable end 112 of the piezoelectric element 106 such that the coupler 146 pushes and pulls the piezoelectric element 106 according to motion by the proof mass 102.

In another aspect of this embodiment, the coupler span retaining surface 148 fixidly holds the coupler span 128 and the coupler cavity 150 slidably holds a movable end 112 of the piezoelectric element 106, where the coupler 146 pushes and pulls the piezoelectric element 106 according to motion by the proof mass 102.

In a further aspect of this embodiment, the coupler span middle section 128 has a sliding surface (not shown) that enables the middle section 128 to slide on the piezoelectric element 106 as the proof mass 102 moves, where the coupler span middle section 132 pushes the piezoelectric element 106.

In yet another aspect of this embodiment, the coupler span middle section 132 has a rounded surface (not shown) that rolls on the piezoelectric element 106 as the proof mass 102 moves, where the coupler span middle section 132 pushes the piezoelectric element 106.

In the embodiment shown in FIGS. 1(a)-1(c) the mechanical transfer assembly 104 actuates two piezoelectric beams 106 mounted parallel to two sides of the housing 108. Because the force from the proof mass 102 is amplified, standard size bulk material piezoelectric 106 unimorphs or bimorphs can be used. The piezoelectric beams 106 deflect up against a constant curvature control surface 114 in both directions. It should be obvious to one skilled in the art that multiple piezoelectric beams 106 can be used with multiple control surfaces 114.

The necessary electrical circuitry to retrieve the created energy from the piezoelectric element 106 are not shown for illustrative clarity.

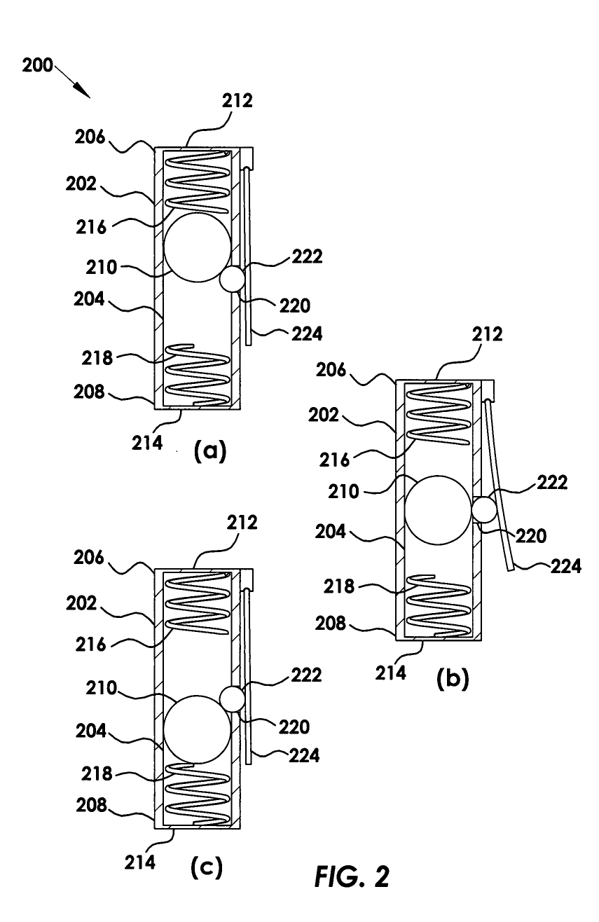

FIGS. 2(a)-(c) show an alternate embodiment of the invention that includes planar partial-cutaway views of a tube-shaped inertial piezoelectric energy scavenger 200. Here, a housing 202 has a track 204 having a first end 206 and a second end 208, where the proof mass 210 moves therein. The housing 202 further has a first proof mass stop 212 disposed at the track first end 206 and a second proof mass stop 214 disposed at the track second end 208, and a first restoring spring 216 disposed at the first stop 212 and a second restoring spring 218 disposed at the second stop 214. In this embodiment, the mechanical assembly has at least one actuation channel 220 disposed transverse to a longitudinal length of the track 204, and a mechanical transfer element 222, where the actuation channel 220 holds the mechanical transfer element 222 and the mechanical transfer element 222 is moveable within the actuation channel 220. The mechanical transfer element 220 abuts the piezoelectric element 224, and the proof mass 210 abuts the mechanical transfer element 222 to move the mechanical transfer element 222 within the actuation channel 220. The mechanical transfer element 222 moves the piezoelectric element 224 as the proof mass 210 moves between the restoring springs (216/218) according to forces applied to the housing 202. The housing 202 holds the piezoelectric element 224 outside of the track 204.

In one aspect of this embodiment 200, the mechanical transfer element 222 is an actuation ball that rolls within the actuation channel 220. In a further aspect, the proof mass 210 is a spherical proof mass. Additionally the track 204 may be a tube, or a curved tube, and the curved tube may be a constant-radius tube or a variable-radius tube. In another aspect of the current embodiment 200, the tube may have a circular or square cross-section. In one aspect of the current embodiment 200, the mechanical transfer element 220 can be an actuation cylinder (not shown) that has a rounded top and a rounded bottom, where the actuation cylinder is slidable within the actuation channel 220.

As shown, the embodiment of FIG. 2(a)-(c) accomplishes the mechanical transfer assembly functions with rolling spherical contacts. The proof mass 210 is implemented as a sphere, which rolls back and forth inside a track 204 or tube. As the spherical proof mass 210 passes through its center point, it pushes a smaller actuation ball 222 orthogonal to the direction of motion of the larger proof mass sphere 210. This smaller actuation sphere 222 actuates a piezoelectric beam 224 attached along the length of the housing 202, where the invention clearly reorients the direction of motion. Force amplification is accomplished by relative radii of the two balls (210/222) and the distance the larger spherical proof mass 210 is allowed to roll. Force amplification values up to about 10 are possible. As shown, a single beam 224 is actuated. However, more than one beam 224 can easily be placed around the proof mass 210 and actuated. The motion of the larger spherical proof mass 210 is bi-stable with a stable point at each end of the track 204 in which it rolls. The unstable equilibrium point is at the center of the track 204. Regardless of the magnitude of the input excitation, the maximum deflection of the piezoelectric beam 224 is determined by the radii of the two balls (210/222) and their initial position. Therefore the piezoelectric beam 224 cannot be overstrained by the proof mass 210. Finally, the beam 224 can be pre-stressed by the relative positions of the balls (210/222), housing 202, and piezoelectric beams 224 (not shown). This compressive bias stress can be achieved during assembly. Although spheres (210/222) are used in this example, any object with a shaped edge profile along the axis of the motion of the proof mass 210 that is in constant contact with another object having a preferred edge profile specifically designed to mate with the sliding profile can produce the motion translation and force amplification described in this invention. The restoring springs (216/218) placed at each end of the track in which the spherical proof mass 210 travels, allows some of the energy to be re-imparted to the proof mass ball 210, rather than losing all of the kinetic energy in the proof mass 210 as it contacts the end stops (212/214). According to the present embodiment, by placing the energy scavenger 200 on a rotating wheel (not shown), such as is the case in a tire pressure monitoring system, the track 204 can be curved to the same radius as the wheel, or a smaller radius than the wheel. This assists centering the spherical proof mass 210 in the track 204, which in turn can provide increased tolerance to misalignment. Additionally, if the radius of the track 204 is smaller than the wheel radius, the resonance of the system is affected. Thus, the track radius can be chosen, in conjunction with spring constants to tune the resonance frequency of the energy harvesting system.

The necessary electrical circuitry to retrieve the created energy from the piezoelectric element 224 are not shown for illustrative clarity.

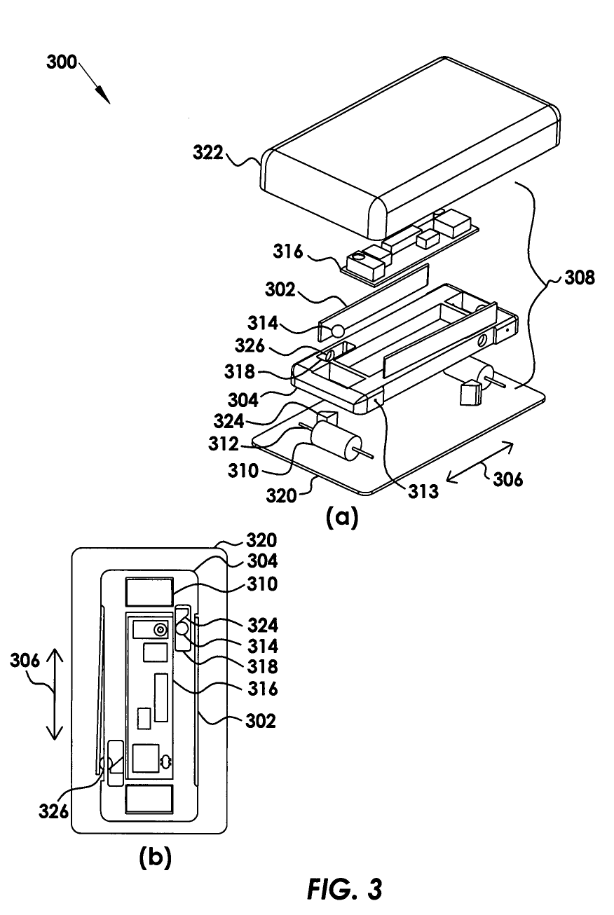

FIGS. 3(a) and 3(b) show an exploded perspective view and a planar top view of another embodiment of the invention, where FIG. 3(b) has the device cover removed for illustrative purposes. Shown is an effective proof mass embodiment 300 that reverses the actuation mass mechanism from an independent rolling element acting on stationary beams to a moveable housing with beams acting against a stationary amplification profile. The inertial energy scavenger effective proof mass embodiment 300 has at least one piezoelectric element 302 held by a translating housing 304, where the direction translation 306 is in a direction parallel to the piezoelectric element 302. A proof mass held in said housing, where the proof mass is an effective proof mass 308 made up of a combination of at least one roller 310 having a roller axis 312 perpendicular to the translation direction 306 and the axis 312 couples to a bearing 313 in the housing 304, at least one piezoelectric element 302, the housing 304, at least one work transfer element 314, and the energy scavenger electronics 316. The housing 304 has at least one actuator channel 318, where the actuator channel 318 is along the translation direction 306. A stationary base 320 and a stationary cover 322 are shown, where the base 320 has at least one actuator 324 disposed perpendicular to the base 320. The actuator 324 has an angled surface disposed perpendicular to the base 320. The actuator channel 318 holds the actuator 324 therein when the housing 304 translates. A mechanical assembly disposed between the actuator channel 318 and the piezoelectric element 302, where the mechanical assembly transfers work from the proof mass (or effective proof mass) 308 to the piezoelectric element 302 when acted on by the actuator 324. The mechanical assembly includes a work transfer port 326 and the work transfer element 314, where the work transfer port 326 spans from an inside wall of the actuator channel 318 through an outside wall of the housing 304, and where the transfer element 314 moves within the transfer port 326 when acted on by the actuator 324. Here, the work transfer element 314 can be a roller ball or a sliding cylinder. According to the present embodiment 300, the work from the effective proof mass 308 is an effective force along the first distance and work to the piezoelectric element is a second effective force along the second distance, where the first distance is greater than the second distance and the first effective force is smaller than the second effective force.

In another aspect of the current embodiment 300, the piezoelectric element 302 is a cantilever piezoelectric element having a first end 326 connected to the housing 304 and a second end 328 coupled to the mechanical assembly. The cantilever piezoelectric element 302 can have the first end 326 larger than the cantilever second end 328 (not shown). Though not shown in the drawings, it should be understood the piezoelectric element 302 can be a fixed-fixed supported piezoelectric element 302 having a first end 326 and a second end 328 connected to the housing 304 and a middle section engaging the mechanical assembly.

According to one aspect of the current embodiment 300, the housing 304 can have a displacement control surface (not shown) interfacing the piezoelectric element 302, where the control surface is curved (see FIG. 1).

In another aspect of the current embodiment, the base 320 can have restoring springs (not shown) disposed to oppose the housing 304 translation.

The necessary electrical circuitry to retrieve the created energy from the piezoelectric element 106 are not shown for illustrative clarity.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. For example, in the cross spring mechanism 116 of FIG. 1(b) can be replaced by various multi-bar configurations to control proof mass 102 translation with alternative compliant mechanisms to provide reduced friction and/or stiffness movement.

The rolling spherical proof mass 210 of FIG. 2 within the tube 202 can be replaced by different shapes to control the deflection profile of the piezo electric beam 224 while altering contact forces that can alter energy transfer. The rolling motion can be replaced by sliding motion. The tube 202 containing the moving proof mass 210 can have alternative cross sectional shapes to further control proof mass 210 motion and frictional forces.

The rolling proof mass of FIGS. 3(a) and 3(b) containing the piezoelectric elements 302 and associated signal conditioning can be designed to use translation mechanisms other than rolling elements such as sliding or multiflexing structures.

All such variations are considered to be within the scope and spirit of the present invention
as defined by the following claims and their legal equivalents.

What is claimed:

1. An inertial energy scavenger comprising:
a. at least one piezoelectric element held by a housing;
b. a proof mass that is movable within said housing, wherein said movement is in a direction parallel to said piezoelectric element; and
c. a mechanical assembly disposed between said proof mass and said piezoelectric element, wherein said mechanical assembly transfers work from said proof mass to said piezoelectric element, whereby said work from said proof mass comprises a first force along a first distance and said work to said piezoelectric element comprises a second force along a second distance, whereas said first distance is greater than said second distance and said first force is smaller than said second force.

2. The inertial energy scavenger of claim 1, wherein said piezoelectric element is a cantilever piezoelectric element having a first end connected to said housing and a second end coupled to said mechanical assembly.

3. The inertial energy scavenger of claim 2, wherein said cantilever first end is larger than said cantilever second end.

4. The inertial energy scavenger of claim 1, wherein said piezoelectric element is a fixed-fixed supported piezoelectric element having a first end and a second end connected to said housing and a middle section coupled to said mechanical assembly.

5. The inertial energy scavenger of claim 1, wherein said housing comprises at least one displacement control surface interfacing said piezoelectric element, wherein said control surface is curved.

6. The inertial energy scavenger of claim 1, wherein said proof mass within said housing has at least one stable equilibrium point, whereby when at said stable equilibrium point said piezoelectric element is at a minimum deflection.

7. The inertial energy scavenger of claim 1, wherein said proof mass within said housing has at least one unstable equilibrium point, whereby when in said unstable equilibrium point said piezoelectric element is at a maximum deflection.

8. The inertial energy scavenger of claim 1, wherein said mechanical assembly comprises at least one bi-lever work transfer element and at least one piezoelectric element coupler.

9. The inertial energy scavenger of claim 8, wherein said bi-lever work transfer element comprises:
a. a proof mass connection end, wherein said connection end connects said proof mass to said bi-lever;
b. a top lever, wherein said top lever comprises:
i. a top lever first end;
ii. a top lever middle section; and
iii. a top lever second end, whereby said top lever first end is attached to said proof mass connection end, whereas said top lever middle section extends in a first diagonal direction from said connection end;
c. a coupler span, wherein said coupler span comprises:
i. a coupler span top end;
ii. a coupler span middle section; and
iii. a coupler span bottom end, whereby said coupler span top end is connected to said second end of said top lever, whereas said coupler span middle section is disposed along said piezoelectric element;
d. a bottom lever, wherein said bottom lever comprises:
i. a bottom lever first end;
ii. a bottom lever middle section; and
iii. a bottom lever second end, whereby said bottom lever first end is attached to said coupler span bottom end, whereas said bottom lever middle section extends in a second diagonal direction from said coupler span bottom end, wherein said bottom lever second end slidably contacts a planar surface within said housing, whereby said planar surface is perpendicular to said movement of said proof mass.

10. The inertial energy scavenger of claim 8, wherein said piezoelectric element coupler comprises a coupler span retaining surface and a coupler cavity, whereby said retaining surface slidably holds said coupler span and said coupler cavity fixedly holds a movable end of said piezoelectric element, whereas said coupler pushes and pulls said piezoelectric element according to motion by said proof mass.

11. The inertial energy scavenger of claim 8, wherein said piezoelectric element coupler comprises a coupler span retaining surface and a coupler cavity, whereby said retaining surface fixidly holds said coupler span and said coupler cavity slidably holds a movable end of said piezoelectric element, whereas said coupler pushes and pulls said piezoelectric element according to motion by said proof mass.

12. The inertial energy scavenger of claim 8, wherein said coupler span middle section comprises a sliding surface, whereby said sliding surface enables said coupler span middle section to slide on said piezoelectric element as said proof mass moves, whereas said coupler span middle section moves said piezoelectric element.

13. The inertial energy scavenger of claim 8, wherein said coupler span middle section comprises a rounded surface, wherein said round surface rolls on said piezoelectric element as said proof mass moves, whereas said coupler span middle section moves said piezoelectric element.

14. The inertial energy scavenger of claim 1, wherein said housing comprises;
a. a track having a first end and a second end, whereby said proof mass moves therein;
b. a first proof mass stop disposed at said track first end and a second proof mass stop disposed at said track second end; and
c. a first restoring spring disposed at said first stop and a second restoring spring disposed at said second stop.

15. The inertial energy scavenger of claim 14, wherein said mechanical assembly comprises:
a. at least one actuation channel disposed transverse to a longitudinal length of said track, and
b. a mechanical transfer element, whereby said actuation channel holds said mechanical transfer element and said mechanical transfer element is moveable within said actuation channel, whereas said mechanical transfer element abuts said piezoelectric element, and wherein said proof mass abuts said mechanical transfer element and moves said mechanical transfer element within said actuation channel, whereby said mechanical transfer element moves said piezoelectric element as said proof mass moves between said restoring springs according to forces applied to said housing.

16. The inertial energy scavenger of claim 14, wherein said mechanical transfer element is an actuation ball, whereas said actuation ball rolls within said actuation channel.

17. The inertial energy scavenger of claim 14, wherein said mechanical transfer element is an actuation cylinder, whereas said actuation cylinder has a rounded top and a rounded bottom, whereby said actuation cylinder is slidable within said actuation channel.

18. The inertial energy scavenger of claim 14, wherein said housing holds said piezoelectric element outside of said track.

19. The inertial energy scavenger of claim 14, wherein said proof mass is a spherical proof mass.

20. The inertial energy scavenger of claim 14, wherein said track is a tube.

21. The inertial energy scavenger of claim 14, wherein said tack is a curved tube.

22. The inertial energy scavenger of claim 20, wherein said curved tube is selected from a group consisting of a constant-radius tube and a variable-radius tube.

23. An inertial energy scavenger comprising:
a. at least one piezoelectric element held by a translating housing, wherein said translation is in a direction parallel to said piezoelectric element;
b. a proof mass held in said housing;
c. at least one actuator channel, wherein said actuator channel is along said translation direction;
d. a stationary base, wherein said base comprises at least one actuator disposed perpendicular to said base, whereby said actuator channel holds said actuator therein when said housing translates; and
e. a mechanical assembly disposed between said actuator channel and said piezoelectric element, wherein said mechanical assembly transfers work from said proof mass to said piezoelectric element when acted on by said actuator, whereby said work from said proof mass comprises a first force along a first distance and said work to said piezoelectric element comprises a second force along a second distance, whereas said first distance is greater than said second distance and said first force is smaller than said second force.

24. The inertial energy scavenger of claim 23, wherein said proof mass is an effective proof mass, whereby said effective proof mass comprises:
a. at least one roller having a roller axis perpendicular to said translation direction;
b. at least one said piezoelectric element;
c. said housing;
d. said mechanical assembly; and
e. energy scavenger electronics, whereby work from said effective proof mass comprises an effective force along said first distance and work to said piezoelectric element comprises a second effective force along said second distance, whereas said first distance is greater than said second distance and said first effective force is smaller than said second effective force.

25. The inertial energy scavenger of claim 23, wherein said piezoelectric element is a cantilever piezoelectric element having a first end connected to said housing and a second end coupled to said mechanical assembly.

26. The inertial energy scavenger of claim 25, wherein said cantilever first end is larger than said cantilever second end.

27. The inertial energy scavenger of claim 23, wherein said piezoelectric element is a fixed-fixed supported piezoelectric element having a first end and a second end connected to said housing and a middle section coupled to said mechanical assembly.

28. The inertial energy scavenger of claim 23, wherein said housing comprises at least one displacement control surface interfacing said piezoelectric element, wherein said control surface is curved.

29. The inertial energy scavenger of claim 23, wherein said proof mass comprises at least one roller having a roller axis perpendicular to said translation direction, whereby said axis couples to a bearing in said housing.

30. The inertial energy scavenger of claim 23, wherein said actuator comprises an angled surface disposed perpendicular to said base.

31. The inertial energy scavenger of claim 23, wherein said mechanical assembly comprises;
a. a work transfer port, wherein said transfer port spans from an inside wall of said actuator channel through an outside wall of said housing; and
b. a work transfer element, wherein said transfer element moves within said transfer port when acted on by said actuator.

32. The inertial energy scavenger of claim 31, wherein said work transfer element is selected from a group consisting of a roller ball, and a sliding cylinder.

33. The inertial energy scavenger of claim 23, wherein said base further comprises restoring springs, whereby said restoring springs are disposed to oppose said housing translation.
